(19) United States
(12) Patent Application Publication
(10) Pub. No.: US 2026/0040918 A1
(43) Pub. Date: Feb. 5, 2026

(54) BIT LINE AND SOURCE LINE CONNECTIONS FOR A 3-DIMENSIONAL ARRAY OF MEMORY CIRCUITS

(71) Applicant: SUNRISE MEMORY CORPORATION, San Jose, CA (US)

(72) Inventors: Shohei Kamisaka, Kanagawa (JP); Yosuke Nosho, Tokyo (JP)

(21) Appl. No.: 19/351,839

(22) Filed: Oct. 7, 2025

Related U.S. Application Data
(63) Continuation of application No. 17/548,034, filed on Dec. 10, 2021, now Pat. No. 12,463,138.
(60) Provisional application No. 63/128,347, filed on Dec. 21, 2020.

(51) Int. Cl. H01L 23/535; H01L 21/768; H01L 23/528; H01L 23/532

(52) U.S. Cl. CPC H01L 23/535; H01L 21/76805; H01L 21/76831; H01L 21/7684; H01L 21/76895; H01L 23/5283; H01L 23/53266; H01L 23/53271; H01L 23/5329

(57) ABSTRACT

A conductor-filled via formed in a staircase structure that is provided in conjunction with a 3-dimensional array of memory strings, where the staircase structure includes multiple steps with each step including a bit line layer and a source line layer. The conductor-filled via includes a conductor to electrically connect a top layer in a first step in the staircase structure to a buried contact provided under the staircase structure, the top layer being the bit line layer or the source line layer of the first step; and a spacer insulator lining the sidewalls of the conductor-filled via to isolate the conductor from at least a bottom layer of the first step and the bit line layer or the source line layer in any steps between the first step and the buried contact.

### CROSS REFERENCE TO RELATED APPLICATIONS

This application is a continuation of co-pending U.S. patent application Ser. No. 17/548,034, entitled BIT LINE AND SOURCE LINE CONNECTIONS FOR A 3-DIMENSIONAL ARRAY OF MEMORY CIRCUITS, filed Dec. 10, 2021, which is incorporated herein by reference for all purposes.

The present application relates to and claims priority of U.S. provisional application (“Provisional Application”), Ser. No. 63/128,347, entitled “Bit Line And Source Line Connections For A 3-Dimensional Array of Memory Circuits,” filed on Dec. 21, 2020. The disclosure of the Provisional Application is hereby incorporated by reference in its entirety.

The present application is also related to U.S. patent application Ser. No. 16/914,089, entitled “Fabrication Method for a 3-Dimensional NOR Memory Array,” filed on Jun. 26, 2020, now U.S. Pat. No. 11,177,281, issued Nov. 16, 2021, which is a continuation of U.S. patent application Ser. No. 16/510,610, entitled “Fabrication Method for a 3-Dimensional NOR Memory Array,” filed on Jul. 12, 2019, now U.S. Pat. No. 10,741,581, issued on Aug. 11, 2020. The disclosure of the Application is hereby incorporated by reference in its entirety.

### BACKGROUND OF THE INVENTION

### 1. Field of the Invention

The present invention relates to semiconductor memory circuits. In particular, the present invention relates to providing via connecting for accessing bit lines and source lines of a 3-dimensional array of memory or storage transistors.

### 2. Discussion of the Related Art

The Copending Application discloses a staircase structure for accessing bit lines and source lines of a 3-dimensional array of horizontal NOR (“HNOR”) memory strings. In that disclosure, the 3-dimensional array of HNOR memory strings comprises thin-film storage transistors formed above a planar surface of a semiconductor substrate. At or on the planar surface of the semiconductor substrate are formed various voltage sources, sense amplifiers and other circuitry suitable for use in HNOR memory string operations. In addition, multiple layers of interconnect conductors are provided both above and beneath the 3-dimensional array. The staircase structure allows a first type of via connections that provide access to bit lines or source lines of the HNOR memory strings of the 3-dimensional array at various steps of the staircase structure from a layer of the interconnect conductors provided above the 3-dimensional array. A second type of via connections allows access from that layer of interconnect conductors to the circuitry at or on the planar surface of the semiconductor substrate. Conductors in that layer of interconnect conductors may be used to interconnect the first and second types of via connections.

To further illustrate, FIG. 1(a) shows a top view (i.e., over an X-Y plane) of a staircase portion at an interconnect conductor layer above a 3-dimensional array of HNOR memory strings of the type disclosed in the Copending Application. For clarity and to facilitate the detailed description herein, a cartesian coordinate system is adopted in which the Z-direction represents the direction substantially normal to the semiconductor substrate and the X- and X-directions represent orthogonal directions in a plane substantially parallel the planar surface of the semiconductor substrate. In FIG. 1(a), via connections 104-1 to 104-4 represents metal-filled vias that provide connections between an interconnection conductor layer above the 3-dimensional array and an interconnection conductor layer beneath the 3-dimensional array (i.e., the second type of via connections). Via connections 103-1 to 103-4 represents metal-filled vias that provide connections between an interconnection conductor layer above the 3-dimensional array and various layers of bit lines that extend from the array portion (i.e., the portion of the 3-dimensional array at which the storage transistors of the HNOR memory strings are located). Via connections 103-1 to 103-4 belong therefore to the first type of via connections.

Conductors 102-1 to 102-4 are conductors in an interconnection conductor layer above the 3-dimensional array routing signals between via connections 103-1 to 103-4 and via connections 104-1 to 104-4, respectively.

FIG. 1(b) shows cross-sections 101-1 and 101-2, which are respectively X-Z plane cross sections along lines A-A′ and B-B′ annotated on FIG. 1(a). As shown in FIG. 1(b), cross-section 101-1 shows via-connections 103-1 to 103-4 extending from the interconnection conductor layer of FIG. 1(a) to the bit lines extended from the array portion of the 3-dimensional array. Cross-section 101-2 shows via connections extending from the interconnection conductor layer of FIG. 1(a) to an interconnection conductor layer beneath the 3-dimensional array. The interconnection conductor layer beneath the 3-dimensional array in FIG. 1(b) routes signals from the circuitry at or on the planar surface of the semiconductor substrate to via connections 104-1 to 104-4. FIG. 1(b) also shows via connections 105-1 to 105-4, which route signals from via connections 104-1 and 104-4, respectively, to other circuitry (e.g., circuitry at the periphery, such as an interface to an external circuit).

A similar signal routing scheme may be provided between the source lines of the 3-dimensional array and the circuitry at or on the planar surface of the semiconductor substrate.

The signal routing between the bit line and the circuitry at or on the planar surface of the semiconductor substrate, as illustrated in FIGS. 1(a) and 1(b), requires both silicon real estate (i.e., at least two via connections for each bit line at each step of the staircase). and conductors in at least one interconnection conductor layer. As known to those of ordinary skill in the art, both silicon real estate and conductors in interconnection conductor layers are precious resources in memory circuits. Any reduction in such resource requirements is highly desirable.

### SUMMARY OF THE INVENTION

According to one embodiment of the present invention, a process includes: (a) providing a one or more buried contacts above a planar surface of a semiconductor substrate; (b) creating a staircase structure in conjunction with a 3-dimensional array of memory cells formed above the buried contacts, the staircase structure comprising a plurality of steps, wherein (i) each step being aligned to one of the buried contacts along a first direction substantially normal to the planar surface; and (ii) at the top of each step, a plurality of layers, one on top of another, including, a bit line layer, a source line layer and a first isolation layer between the source line layer and the bit line layer, with either the bit line layer or the source line layer being closer to the top of each step than the other; (c) providing a second isolation layer over the staircase structure; (d) creating a trench at each step that extends along the first direction through the second isolation layer and the step to the buried contact; (c) depositing a spacer insulator in each trench and etching back the spacer insulator, so as to expose a portion of the layer at the top of each step and the buried contact and so that the spacer insulator lines sidewalls of the trench between the top of each step and the exposed buried contact; and (f) filling each trench with a conductor.

In some embodiments, the process further includes (a) planarizing the conductor-filled trench; (b) providing a third isolation layer over the conductor-filled trench; and (c) creating a via connection to allow access to the conductor-filled trench.

According to another embodiment of the present invention, a process includes (a) creating a staircase structure in conjunction with a 3-dimensional array of memory cells formed above a planar surface of a semiconductor substrate, the staircase structure comprising a plurality of steps, wherein at the top of each step, a plurality of layers, one on top of another, including, a source line layer at the top of each step; (b) providing a second isolation layer over the staircase structure; (c) creating a trench that extends along a first direction substantially normal to the planar surface through the second isolation layer, exposing source line layers at the top of multiple steps; (d) depositing a spacer insulator in the trench and etching back the spacer insulator, so as to expose the source line layers at the top of the steps; and (c) filling each trench with a conductor. In some embodiments, one or more buried contacts may be provided between the planar surface of a semiconductor substrate and the staircase structure, such that creating the trench and etching back the spacer insulator expose one of the buried contacts.

In some embodiments, the circuitry for memory cell operations is formed at or on the planar surface of the semiconductor substrate, and wherein the buried contacts are provided to connect to the circuitry.

According to one embodiment of the present invention, a conductor-filled via formed between an interconnection conductor layer and a buried contact above a planar surface of a semiconductor substrate, includes: (a) a first portion that extends from the interconnection conductor layer through a first isolation layer to a step in a staircase structure that is provided in conjunction with a 3-dimensional array of memory cells formed above the buried contacts, wherein (i) the step of the staircase structure is aligned to the buried contact along a first direction substantially normal to the planar surface of the semiconductor substrate, (ii) at the top of the step, the step comprises a plurality of layers, one on top of another, including, a bit line layer, a source line layer and a second isolation layer between the source line layer and the bit line layer, the bit line layer or the source line layer being the layer at the top of the step, and (iii) the first portion electrically contacting the layer at the top of the step; and (b) a second portion extending from a portion of the step below the layer at the top of the step to the buried contact, wherein a spacer insulator lines sidewalls of the conductor-filled via.

According to another embodiment of the present invention, a conductor-filled via is formed between one or more interconnection conductor layers and two or more steps of a staircase structure in conjunction with a 3-dimensional array of memory cells formed above a planar surface of a semiconductor substrate, wherein (i) the staircase structure comprises a plurality of steps, (ii) at the top of each step, a plurality of layers, one on top of another, including, a source line layer at the top of each step; and (iii) the conductor-filled via being formed inside a spacer insulator that exposes the source line layers at the top of the steps and which insulates the conductor-filled via from conductive layers in the two or more steps of the staircase structure.

According to another embodiment of the present invention, a conductor-filled via is formed in a staircase structure that is provided in conjunction with a 3-dimensional array of memory strings formed above a planar surface of a semiconductor substrate. The 3-dimensional array of memory strings includes multiple layers, formed one on top of another and being isolated from each other by a first isolation layer. Each layer includes a drain layer and a source layer isolated from each other by a second isolation layer. The staircase structure includes multiple steps corresponding to the multiple layers, each step comprising a bit line layer corresponding to the drain layer and a source line layer corresponding to the source layer. The conductor-filled via includes a conductor to electrically connect a top layer in a first step of the multiple steps in the staircase structure to a buried contact provided under the staircase structure and above the planar surface of the semiconductor substrate. The top layer is the bit line layer or the source line layer of the first step. The conductor-filled via further includes a spacer insulator lining the sidewalls of the conductor-filled via to isolate the conductor from at least a bottom layer of the first step and the bit line layer or the source line layer in any steps between the first step and the buried contact, where the bottom layer of the first step is the bit line layer or the source line layer of the first step other than the top layer. The first step of the staircase structure is aligned to the buried contact along a first direction substantially normal to the planar surface of the semiconductor substrate and at least partially overlapping the buried contact along a second direction substantially parallel to the planar surface of the semiconductor substrate. The conductor-filled via is formed in a third isolation layer provided adjacent the first step in the second direction and at least partially overlapping the buried contact. The conductor electrically contacts the top layer of the first step.

The present invention is better understood upon consideration of the detailed description below, in conjunction with the accompanying drawings.

### BRIEF DESCRIPTION OF THE DRAWINGS

FIG. 1(a) shows a top view of a staircase portion at an interconnect conductor layer above a 3-dimensional array of HNOR memory strings of the type disclosed in the Application.

FIG. 1(b) shows cross-sections 101-1 and 101-2, which are X-Z plane cross sections along lines A-A′ and B-B′ annotated on FIG. 1(a).

FIG. 2(a) is a top view of a staircase portion at an interconnect conductor layer above a 3-dimensional array of HNOR memory strings, showing via connections 202-1 to 202-4, in accordance with one embodiment of the present invention; merely for comparison purpose, FIG. 2(a) also shows an area from which via connections 104-1 to 104-4 of FIG. 1 are eliminated.

FIG. 2(b) shows cross-sections 200-1 and 200-2, which are X-Z planes along lines A-A′ and B-B′ of FIG. 2(a), respectively, in accordance with one embodiment of the present invention; line A-A′ cuts across via connections 202-1 to 202-4.

FIGS. 3(a)-1, 3(a)-2, 3(a)-3, 3(b), 3(c), 3(d), 3(e) and 3(f) illustrate a process for providing via connections between the bit lines in staircase structure 304 and (i) the circuitry at or on the planar surface of the semiconductor substrate and (ii) conductors at an interconnection conductor layer above the 3-dimensional array, in accordance with one embodiment of the present invention.

FIG. 4 shows slits 401, 402 and 403, where common via connections may be formed to connect, respectively, (i) source lines at all steps of the staircase structure to a conductor in an interconnection conductor layer under the 3-dimensional array, (ii) source lines at all steps of the staircase structure, without access to buried contact 302 in an interconnection conductor layer under the 3-dimensional array, and (iii) selective source lines, according to one embodiment of the present invention.

FIGS. 5(a), 5(b), 5(c), 5(d) and 5(e) illustrate a process for providing via connections to the source lines of a staircase structure, according to one embodiment of the present invention.

### DETAILED DESCRIPTION OF THE PREFERRED EMBODIMENTS

According to one embodiment of the present invention, via connections that allow access to the bit lines or source lines of a 3-dimensional array of HNOR memory strings from both an interconnection conductor layer above the 3-dimensional array and an interconnection conductor layer beneath the 3-dimensional array are provided. In some embodiments, the interconnection conductor layer under the 3-dimensional array provides connections to buried contacts for accessing the circuitry for HNOR memory string operation in the underlying planar surface of a semiconductor substrate. The via connections of the present invention achieves its connectivity functions without requiring additional real estate or conductor resources in the interconnection conductor layers.

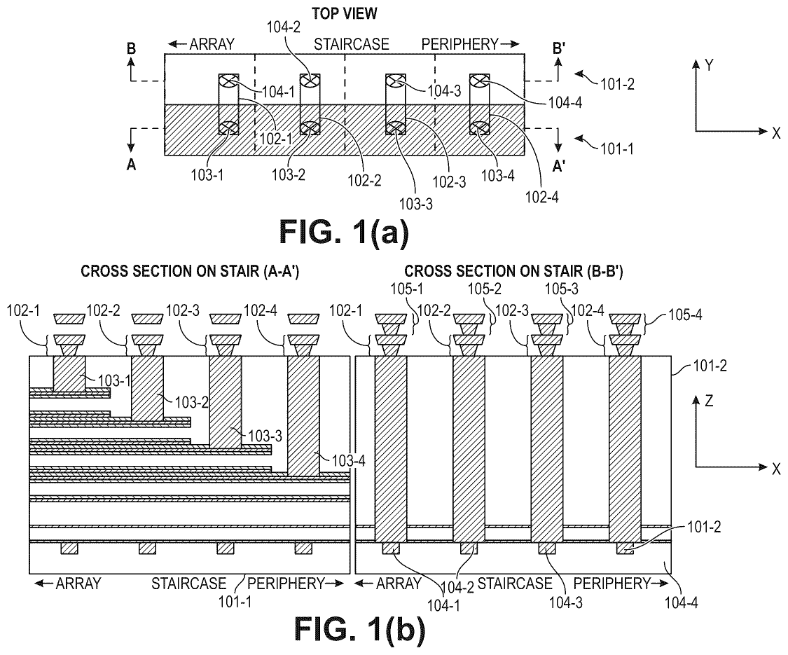

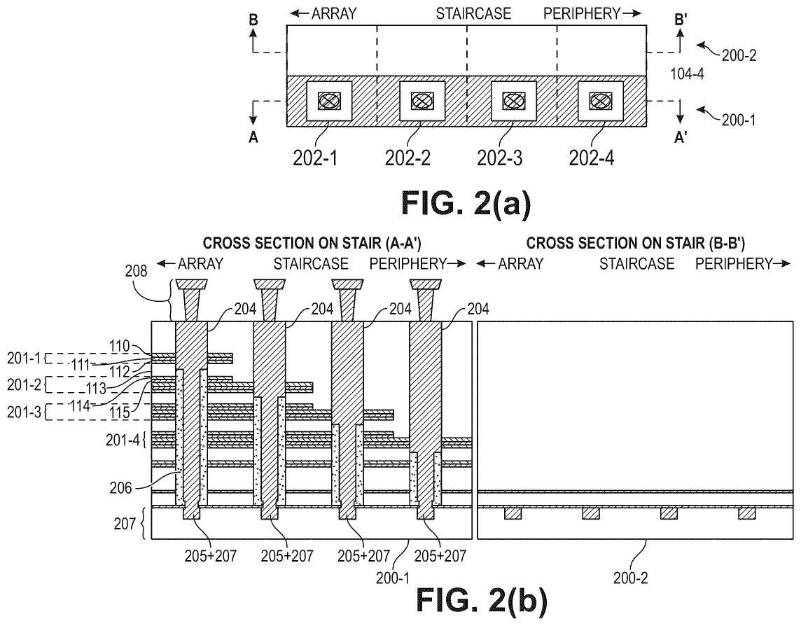

FIG. 2(a) is a top view of a staircase portion at an interconnect conductor layer above a 3-dimensional array of HNOR memory strings, showing via connections 202-1 to 202-4, in accordance with one embodiment of the present invention. Merely for comparison purpose, FIG. 2(a) also shows an area from which via connections 104-1 to 104-4 of FIG. 1 are eliminated. Of course, as demonstrated below, as via connections 104-1 to 104-4 are no longer required, this area need not be provided in any implementation.

FIG. 2(b) shows cross-sections 200-1 and 200-2, which are X-Z planes along lines A-A′ and B-B′ of FIG. 2(a), respectively, in accordance with one embodiment of the present invention. Line A-A′ cuts across via connections 202-1 to 202-4. Via connections 202-1 to 202-4 provide substantially the same functions as the collection of first type of via connections 101-1 to 101-4, the second type of via connections 103-1 to 103-4, and conductors 102-1 to 102-4 connecting between the first and second types of via connections, as shown in FIGS. 1(a) and 1(b), so that via connections 202-1 to 202-4 eliminate the need for the silicon real estate of via connections 104-1 to 104-4 and the requirement for conductors 102-1 to 102-4. For this reason, cross-section 200-2 shows that the area previously occupied by via connections 104-1 to 104-4 are no longer required. In addition, via connections 105-1 to 105-4 of FIG. 1(b)—which route signals from via connections 104-1 and 104-4, respectively, to other circuitry (e.g., circuitry at the periphery, such as an interface to an external circuit)—can now be performed by the via connections and conductors associated with interconnection conductor layer 208.

Cross-section 200-1 of FIG. 2(b) shows steps 201-1 and 201-4, each step extending from the array portion of the 3-dimensional array of HNOR memory strings and comprising: (i) isolation layer (e.g., 30-nm thick silicon oxycarbon (SiOC)) 110, drain conductor layer (e.g., a 40-nm thick metal layer) 111, drain region (e.g., 30-nm thick n+polysilicon) 112, drain-source separation layer (e.g., 100-nm thick silicon oxide) 113, source region (e.g., 30-nm thick n+polysilicon) 114, and source conductor layer (e.g., a 40-nm thick metal layer) 115. Isolation layer 110 provides electrical isolation between adjacent steps. The extensions of drain regions 112 and source regions 114 into the staircase portion of the 3-dimension array serve as the bit lines and source lines, respectively. Drain conductor layer 111 and source conductor layer 115 are optional electrically conducting layers provided to reduce the resistances in the common bit line and the common source line, respectively. In some embodiments, drain conductor layer 111 and source conductor layer 115 may be formed using a metal replacement step that replaces previously deposited sacrificial layers (e.g., silicon nitride layers). At the time via connections 202-1 to 202-4 are completely formed, the metal replacement step may or may not have occurred. Therefore, drain conductor layer 111 and source conductor layer 115 of FIG. 2 may be the sacrificial layers at the time via connections 202-1 to 202-4 are formed.

As shown in cross-section 200-1 of FIG. 2(b), via connections 202-1 to 202-4 are each provided as a conductive pillar that extends from interconnection conductor layer 208 above the 3-dimensional array to interconnection conductor layer 207 beneath the 3-dimensional array. Each conductive pillar of FIG. 2 is shown including (i) first portion 204, which extends from interconnection conductor layer 208 into drain-source separation layer 113 in its step of the staircase structure, and (ii) second portion 205, which extends from drain-source separation layer 113 to interconnection conductor layer 207 beneath the 3-dimensional array. In the embodiment shown in FIG. 2, first portion 204 of the conductive pillar contacts its bit line along its side walls. Second portion 205 of the conductive pillar is electrically isolated from the conductive layers of the other steps along its length by oxide spacer layer 206. For example, as shown in FIG. 2(b), the conductive pillar of via connection 202-1 contacts the bit line of step 201-1 and is electrically insulated from the conductive layers of steps 202-2, 202-3 and 202-4 by oxide spacer layer 206. In some embodiments, during the metal replacement step, the conductive pillars of via connections 202-1 to 202-4 serve as a brace to stabilize the staircase structure, contributing to preventing bending due to the sacrificial material being vacated from drain conductor layer 111 and source conductor layer 115.

In some embodiments, first portion 204 need not extend along the Z-direction into drain-source separation layer 113. It may be sufficient to extend along the Z-direction only as far as contacting drain conductor layer 111 or drain region 112.

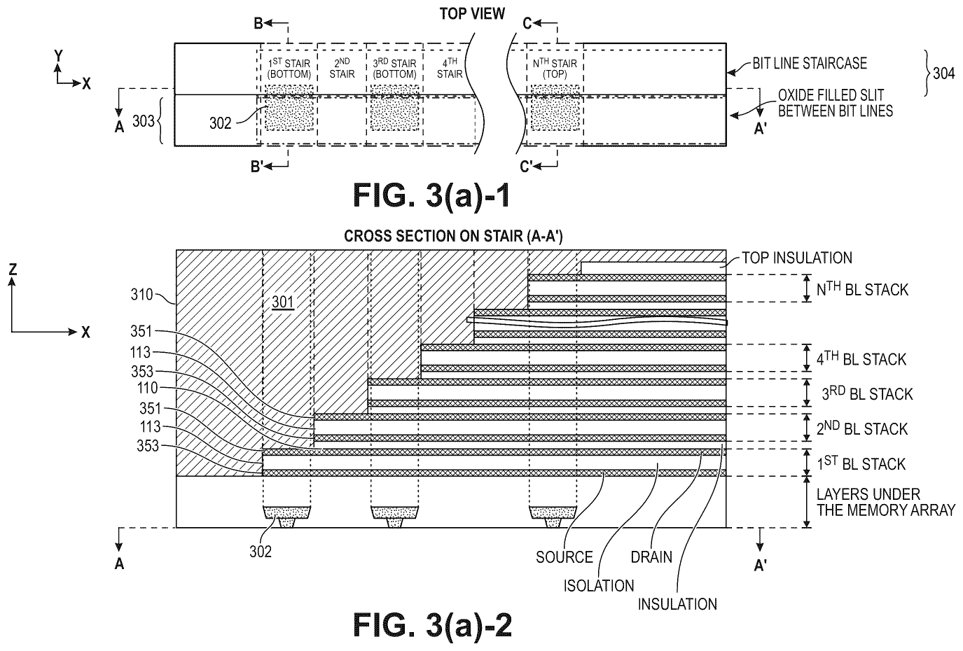

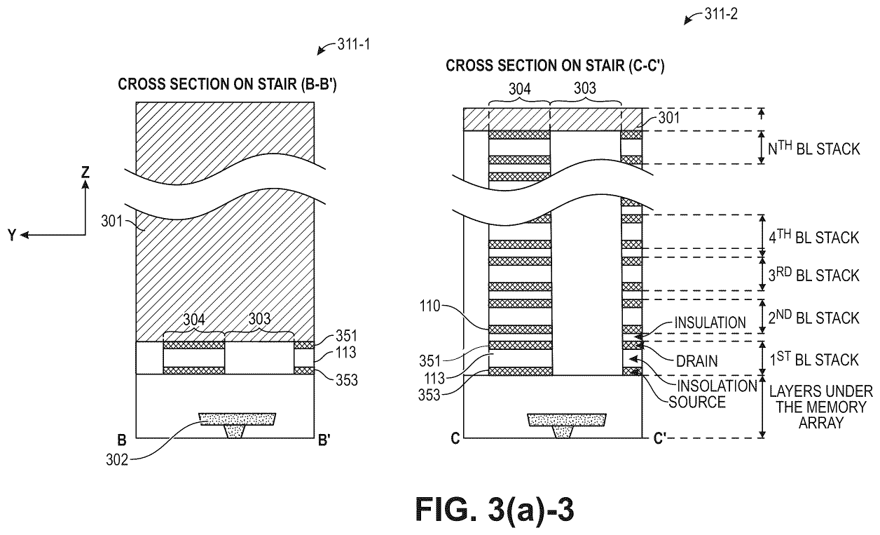

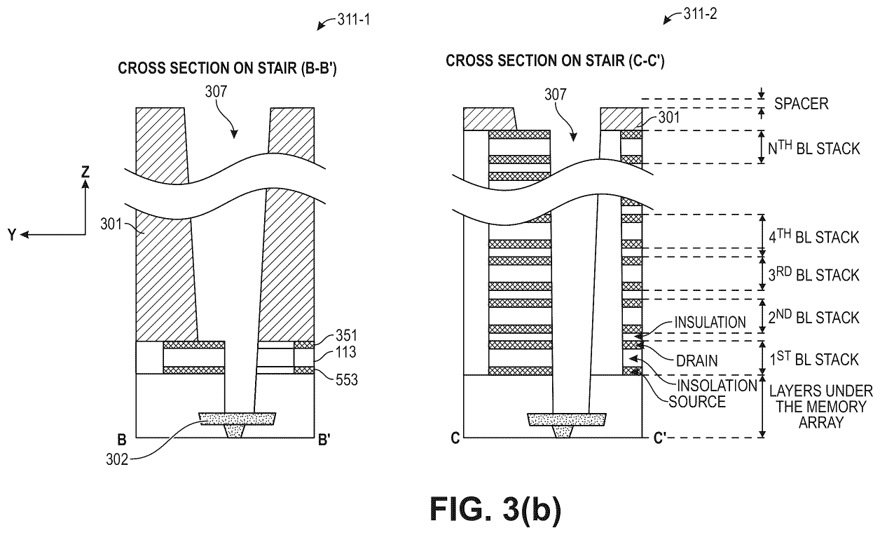

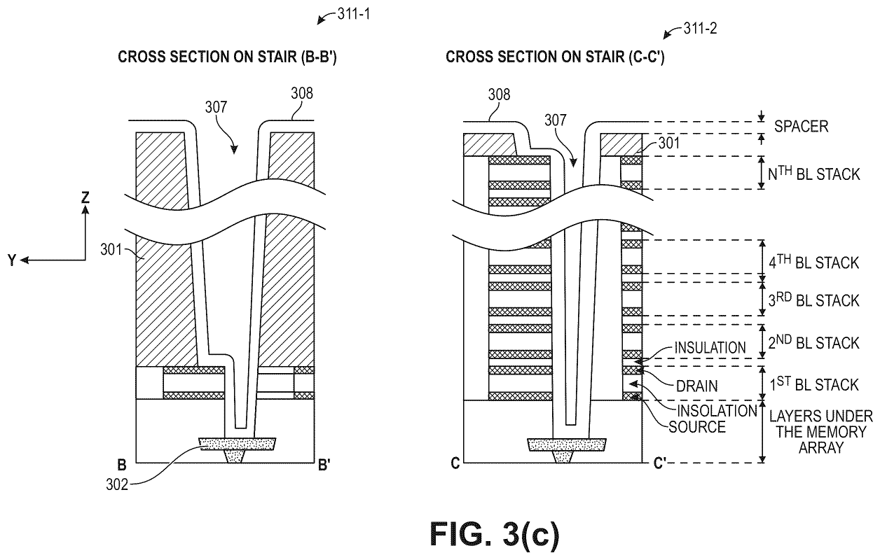

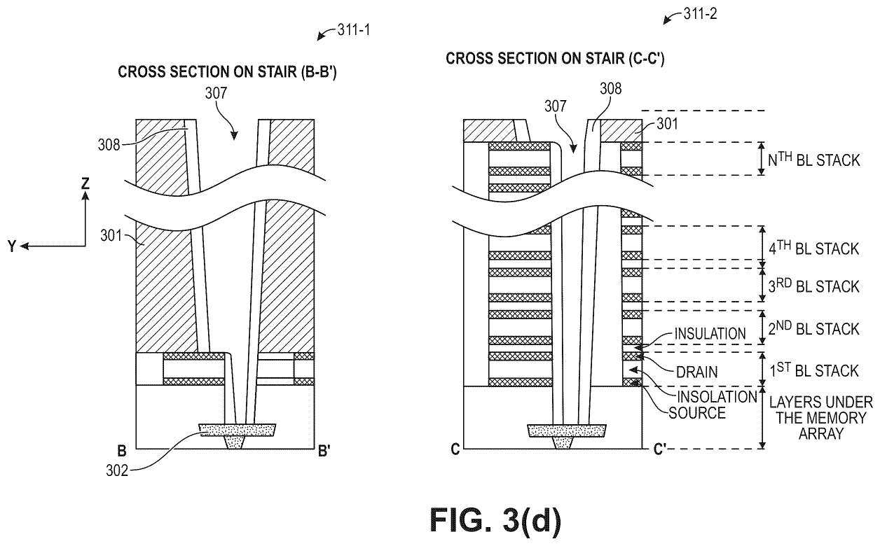

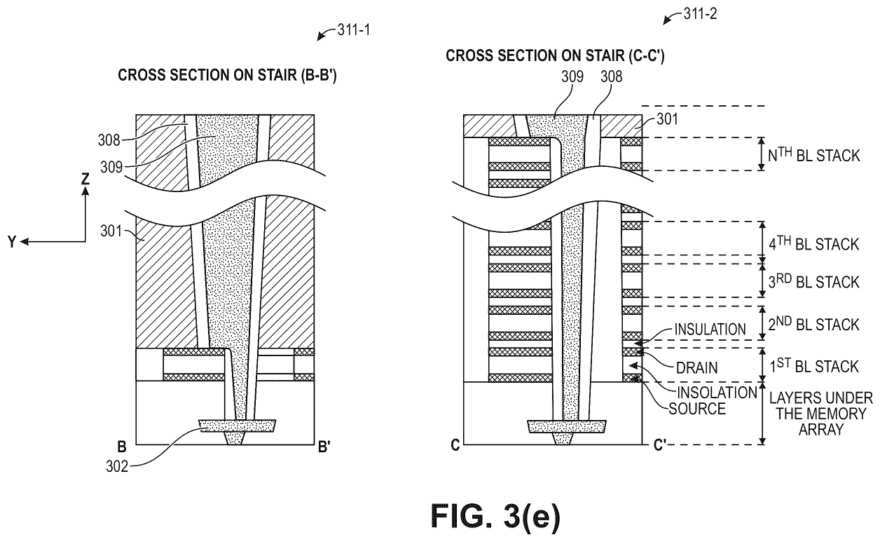

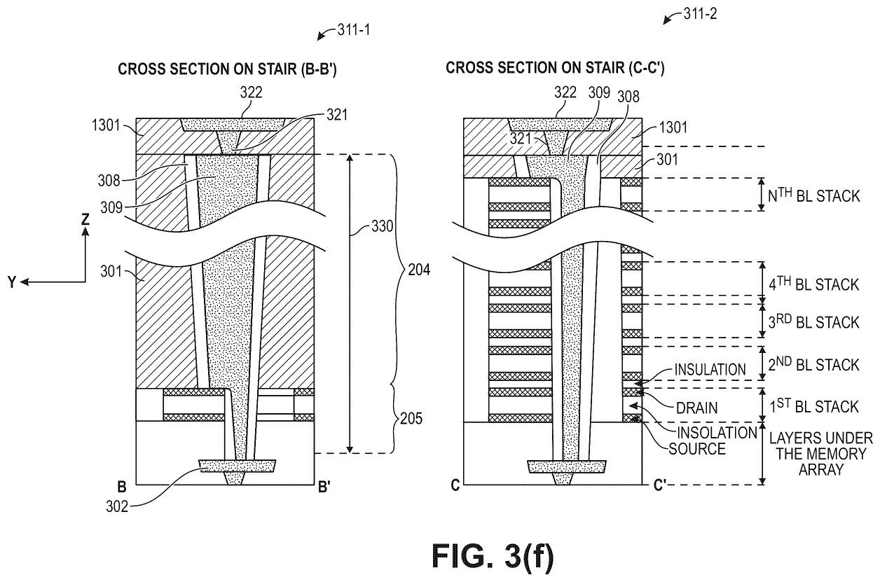

FIGS. 3(a) to 3(f) illustrate a process for providing via connections between the bit lines in staircase structure 304 and (i) the circuitry at or on the planar surface of the semiconductor substrate and (ii) conductors at an interconnection conductor layer above the 3-dimensional array, in accordance with one embodiment of the present invention. Note that, while the principles illustrated in FIGS. 3(a) to 3(f) are applicable may be used to fabricate via connections of FIGS. 2(a) and 2(b) (e.g., via connections 202-1 to 202-4), which is included entirely within the footprint of the staircase portion of the 3-dimensional array, the embodiment illustrated in FIGS. 3(a)-3(f) provides via connections that overlap and extend beyond along the Y-direction a sidewall of the staircase structure, as discussed below.

FIG. 3(a) includes (i) FIG. 3(a)-1, which is a top view (i.e., X-Y plane) of staircase structure 304 with an arbitrary number (n) of steps partially overlapping buried contacts 302 exposed to an interconnect conductor layer underneath the 3-dimensional array, (ii) FIG. 3(a)-2, which is cross-section (Z-X plane) 310 along line A-A′ cutting both staircase structure 304 and buried contacts 302; and (iii) FIG. 3(a)-3, which includes cross-sections (Y-Z planes) 311-1 and 311-2, cutting through lines B-B′ (i.e., at the first step of staircase structure 304) and C-C′ (i.e., at the nth step of staircase structure 304) in FIG. 3(a)-1, respectively. In FIG. 3(a), buried contacts 302 are provided only underneath every other steps of staircase 304 in this side of the array portion of the 3-dimensional array. A similar staircase structure is provided on the opposite side of the array portion of the 3-dimensional array that provides buried contacts underneath the steps for which no buried contacts are provided in staircase 304.

Each of buried contacts 302 extends in the Y-direction beyond staircase structure 304 to overlap oxide-filled area 303 on one side of staircase structure 304. (Thus, the resulting via connections fabricated in the process of FIGS. 3(a)-3(f) overlap and extend beyond along the Y-direction a sidewall of staircase structure 304; see, e.g., FIG. 3(a)-1). In FIGS. 3(a)-1, 3(a)-2 and 3(a)-3, interposer oxide 301 fills the volume above the steps of staircase structure 304, the oxide in interposer oxide 301 may be the same oxide in oxide-filled area 303. For clarity, in FIGS. 3(a)-3(f), each step of staircase 304 are shown represented by drain layer 351, drain-source separation layer 113, source layer 353 and isolation layer 110. Drain layer 351 may be, for example, the combination of drain conductor layer 111 and drain region 112 of FIG. 2. Likewise, source layer 353 may be, for example, the combination of source conductor layer 115 and source region 114 of FIG. 2. FIG. 3(a) shows staircase structure 304 after its formation, an oxide fill step and a planarization step (e.g., by a chemical-mechanical polishing (CMP) step).

Thereafter, after a photo-lithographical patterning step, a contact via etch is performed, which removes interposer oxide 301 above the steps of staircase structure 304 and a part of oxide-filled area 303 to provide trenches 307. The resulting structure is illustrated in cross-sections 311-1 and 311-2 of FIG. 3(b).

Thereafter, a spacer deposition step deposits oxide spacer layer 308 into trenches 307. The resulting structure is illustrated in cross-sections 311-1 and 311-2 of FIG. 3(c). Spacer oxide layer 308 is then anisotropically etched back from each of trenches 307 to expose the top of the step in each trench and buried contact 302 at the bottom of the trench. The resulting structure is illustrated in FIG. 3(d).

Thereafter, trenches 307 may be filled with conductor 309 (e.g., a titanium nitride (TiN) liner, followed by a tungsten (W) fill). A CMP step may planarize the surface of the resulting structure and may remove excess conductor from the surface of the resulting structure. The resulting structure is illustrated in FIG. 3(e).

Thereafter, an addition layer of interposer oxide 1301 (e.g., SiO₂) is provided over the surface and conductor-filled vias (e.g., W) 321 are then provided in interposer oxide 1301 to allow access to conductor 309. Via connection 330 is deemed complete. The resulting structure is illustrated in FIG. 3(f). Indicated in FIG. 3(f) are the portions of the conductive pillar in via connection 330 that correspond to first portion 204 and second portion 205 of the conductive pillar in FIG. 2. Conductors in interconnection conductor layer 322 above the 3-dimensional array may then be used to route signals to via connection 330.

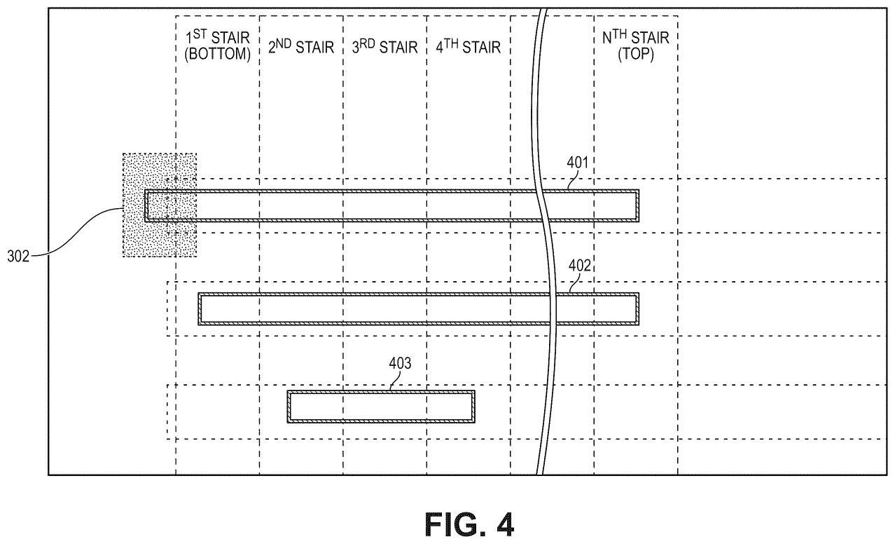

As disclosed in the Copending Application, the source lines of a 3-dimensional array may be biased to a common voltage supplied from one or more voltage sources in the circuitry at or on the planar surface of the semiconductor substrate. Alternatively, selected ones or all source lines may be tied together to allow, during a read, program or erase operation, the source lines to be pre-charged to a common voltage. The total capacitance of the tied source lines may sustain the pre-charged voltage in order to serve as a virtual voltage source (e.g., a virtual ground) during the read, program or erase operation. Thus, unlike the bit lines, via connections to the source line of each individual step of the staircase structure need not be provided. FIG. 4 shows slits 401, 402 and 403, where common via connections may be formed to connect, respectively, (i) source lines at all steps of the staircase structure to a conductor in an interconnection conductor layer under the 3-dimensional array, (ii) source lines at all steps of the staircase structure, without access to buried contact 302 in an interconnection conductor layer under the 3-dimensional array, and (iii) selective source lines, according to one embodiment of the present invention. Slit 401, 402 or 403 may span the steps of the staircase structure along the X-direction but separated in Y-positions from the via connections for the bit lines of the staircase structure.

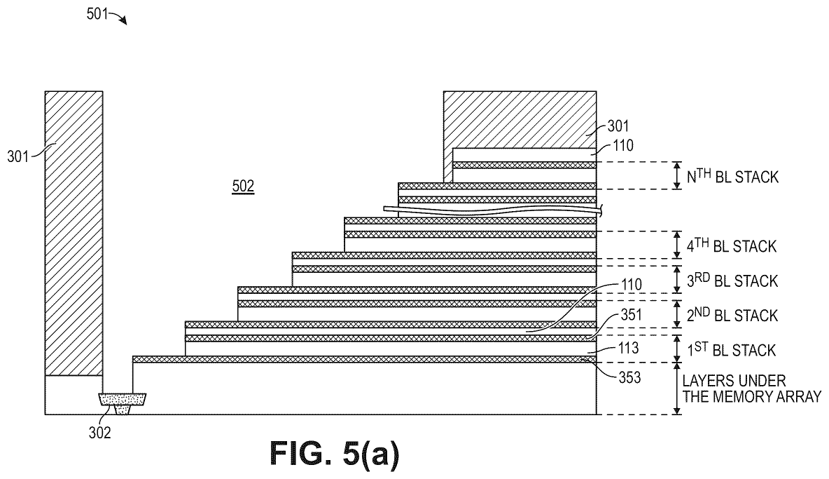

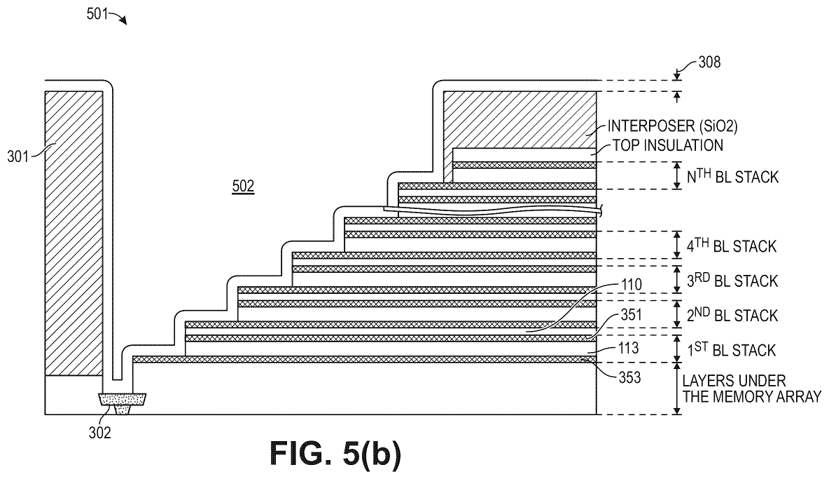

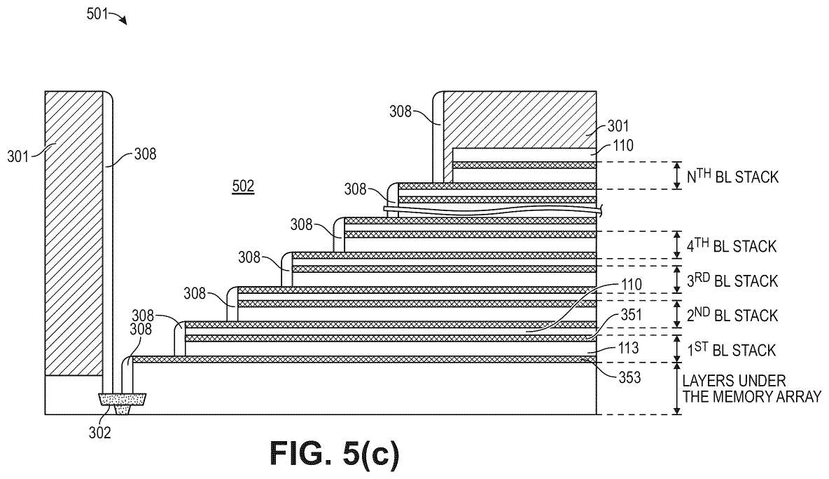

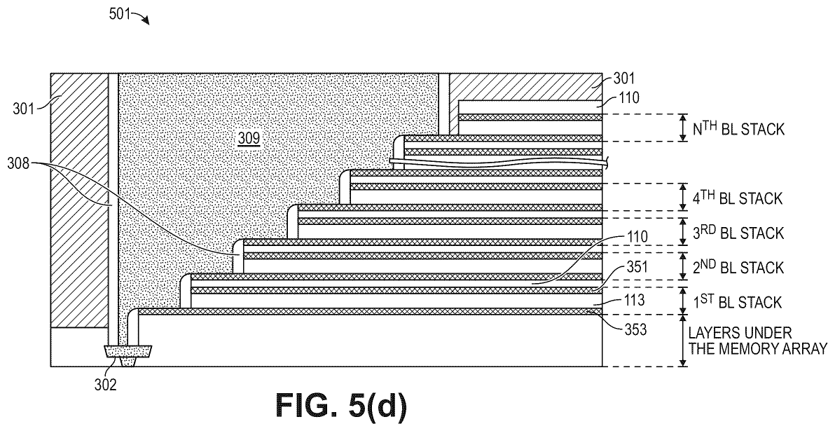

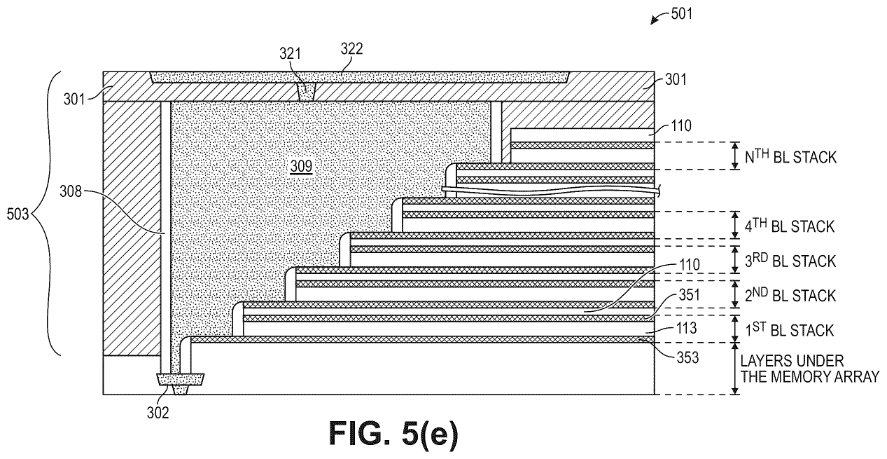

FIGS. 5(a) to 5(c) illustrate a process for providing via connections to the source lines of a staircase structure, according to one embodiment of the present invention. Specifically, FIGS. 5(a) to 5(e) illustrate a process for forming a via connection for source lines of a staircase structure which is accessible from conductors in an interconnection layer above the 3-dimensional array and which connects source lines at all steps of the staircase structure to a conductor in an interconnection conductor layer under the 3-dimensional array (e.g., within slit 401).

Initially, to form the via connection for the source lines, the drain layer and the drain-source separation layer of each step of the staircase structure (e.g., drain layer 351 and drain-source separation layer 113 at each step of staircase structure 304 of FIG. 3(a)) in the vicinity are removed in an etching step. Thereafter, the resulting structure is filled with an oxide (e.g., interposer oxide 301). A photo-lithographical patterning step is then performed on the oxide-filled staircase structure to pattern for the selected common source line via slit (e.g., slit 401 of FIG. 4), followed by a contact via etch. The resulting structure, staircase structure 501, is shown in FIG. 5(a). As shown in FIG. 5(a), trench 502 is formed by removing interposer oxide layer 301 from via slit 401, such that buried contact 302 and source layer 353 of each step of staircase structure 501 are exposed. (To facilitate cross reference, the layers of each step of staircase structure 501 are labeled by the corresponding layers at each step of corresponding staircase structure 304 of FIG. 3—i.e., each step of staircase structure 501 comprises isolation layer 110, drain layer 351, drain-source separation layer 113 and source layer 353.)

A spacer deposition step then deposits oxide spacer layer 308 into trench 502. This spacer deposition step may be carried out concurrently with the spacer deposition step of FIG. 3(c) that is carried out for the bit line via connections. The resulting structure is illustrated in FIG. 5(b).

Spacer oxide layer 308 is then anisotropically etched back in trench 502 to expose source layer 353 on each step and buried contact 302 at the bottom of trench 502. This spacer anisotropical etch step may be carried out concurrently with the spacer anisotropical etch step of FIG. 3(d) that is carried out for the bit line via connections. The resulting structure is illustrated in FIG. 5(c).

Thereafter, trench 502 may be filled with conductor 309 (e.g., a titanium nitride (TiN) liner, followed by a tungsten (W) fill). A CMP step may be applied to planarize the surface of the resulting structure and to remove excess conductor from the surface of the resulting structure. The conductor fill and CMP steps may be carried out concurrently with the conductor fill and CMP steps of FIG. 3(e) that is carried out for the bit line via connections. The resulting structure is illustrated in FIG. 5(d).

Thereafter, an addition layer of interposer oxide 301 (e.g., SiO₂) is provided over the surface and conductor-filled (e.g., W) via 321 is then provided in interposer oxide 301 to allow access to conductor 309. Via connection 503 is deemed complete. One or more conductors in interconnection conductor layer 322 above the 3-dimensional array may then be used to route signals to via connection 503. The interposer oxide deposition, via formation, and formation of interconnection conductor layer 322 may be carried out concurrently with the corresponding steps of FIG. 3(f) that is carried out for the bit line via connections. The resulting structure is illustrated in FIG. 5(e).

The above-detailed description is provided to illustrate specific embodiments of the present invention and is not intended to be limiting. Numerous modifications and variations within the scope of the present invention are possible. The present invention is set forth in the accompanying claims.

1. A conductor-filled via formed in a staircase structure that is provided in conjunction with a 3-dimensional array of memory strings formed above a planar surface of a semiconductor substrate, the 3-dimensional array of memory strings comprising a plurality of layers, formed one on top of another and being isolated from each other by a first isolation layer, each layer comprising a drain layer and a source layer isolated from each other by a second isolation layer, the staircase structure comprising a plurality of steps corresponding to the plurality of layers, each step comprising a bit line layer corresponding to the drain layer and a source line layer corresponding to the source layer, the conductor-filled via comprising:
a conductor to electrically connect a top layer in a first step of the plurality of steps in the staircase structure to a buried contact provided under the staircase structure and above the planar surface of the semiconductor substrate, the top layer being the bit line layer or the source line layer of the first step; and
a spacer insulator lining the sidewalls of the conductor-filled via to isolate the conductor from at least a bottom layer of the first step and the bit line layer or the source line layer in any steps between the first step and the buried contact, the bottom layer of the first step being the bit line layer or the source line layer of the first step other than the top layer,
wherein (i) the first step of the staircase structure is aligned to the buried contact along a first direction substantially normal to the planar surface of the semiconductor substrate and at least partially overlapping the buried contact along a second direction substantially parallel to the planar surface of the semiconductor substrate; (ii) the conductor-filled via is formed in a third isolation layer provided adjacent the first step in the second direction and at least partially overlapping the buried contact; and (iii) the conductor electrically contacts the top layer of the first step.

2. The conductor-filled via of claim 1, wherein the conductor in the conductor-filled via comprises tungsten provided over a titanium nitride liner layer.

3. The conductor-filled via of claim 1, wherein the staircase structure comprises the first step with one or more other steps underneath the first step, the spacer insulator insulting the conductor from the bit line layers and the source line layers of the other steps underneath the first step.

4. The conductor-filled via of claim 1, further comprising:
an interconnection conductor layer provided on a top side of the staircase structure, opposite the planar surface of the semiconductor substrate, and insulated from the staircase structure; and
a second conductor-filled via formed between the interconnection conductor layer and the conductor, wherein the second conductor-filled via is in electrical contact with the conductor of the conductor-filled via and the interconnection conductor layer.

5. The conductor-filled via of claim 4, wherein the second conductor-filled via comprises tungsten.

6. The conductor-filled via of claim 1, wherein the spacer insulator comprises silicon oxide.

7. The conductor-filled via of claim 1, wherein the 3-dimensional array of memory strings comprises a 3-dimensional array of storage transistors organized as horizontal NOR memory strings.

8. The conductor-filled via of claim 1, wherein the third isolation layer comprises a silicon oxide.

9. The conductor-filled via of claim 1, wherein the bit line layer and the source line layer each comprise polysilicon.

10. The conductor-filled via of claim 1, wherein the bit line layer and the source line layer each further comprise a metal layer.

11. A process, comprising:
providing a one or more buried contacts above a planar surface of a semiconductor substrate;
creating a staircase structure in conjunction with a 3-dimensional array of memory strings formed above the buried contacts, the staircase structure comprising a plurality of steps formed one on top of another, wherein (i) each step being aligned to one of the buried contacts along a first direction substantially normal to the planar surface and at least partially overlapping the buried contact along a second direction substantially parallel to the planar surface of the semiconductor substrate; and (ii) each step comprises a plurality of layers, including a bit line layer, a source line layer and a first isolation layer between the source line layer and the bit line layer, the bit line layer or the source line layer forming a top layer of each step;
providing a second isolation layer over the staircase structure;
creating a trench at each step that extends along the first direction through the second isolation layer and the step to the buried contact;
depositing a spacer insulator in each trench and etching back the spacer insulator, so as to expose a portion of the layer at the top layer of each step and the buried contact and so that the spacer insulator lines sidewalls of the trench between the top of each step and the exposed buried contact; and
filling each trench with a conductor, the conductor being in electrical contact with the top layer of the respective step and the respective buried contact.

12. The process of claim 11, further comprising:
planarizing the conductor-filled trench;
providing a third isolation layer over the conductor-filled trench; and
creating a via connection to allow access to the conductor-filled trench.

13. The process of claim 11, wherein the spacer insulator comprises silicon oxide.

14. The process of claim 11, wherein the 3-dimensional array of memory strings comprises a 3-dimensional array of storage transistors organized as horizontal NOR memory strings.

15. The process of claim 11, wherein the conductor comprises tungsten provided over a titanium nitride liner layer.

16. The process of claim 11, wherein the first and second isolation layers comprise silicon oxide.

17. The process of claim 11, wherein the bit line layer and the source line layer each comprise polysilicon.

18. The process of claim 11, wherein the bit line layer and the source line layer each comprise a metal layer.

19. The process of claim 11, wherein the 3-dimensional array of memory string is formed above a planar surface of a semiconductor substrate at which or on which is formed circuitry for memory cell operations, and wherein the buried contacts are provided to connect to the circuitry.

20. The process of claim 11, wherein the spacer insulator isolates the conductor from at least a bottom layer of each respective step and the bit line layer or the source line layer in any steps between the respective step and the buried contact, the bottom layer of each step being the bit line layer or the source line layer of the first step other than the top layer.
